(19) United States
(12) Patent Application Publication
(10) Pub. No.: US 2003/0009878 A1
(43) Pub. Date: Jan. 16, 2003

(54) Method for attaching an electronic component to a substrate

(76) Inventor: John Gregory, Atlanta, GA (US)

Correspondence Address: MANELLI DENISON & SELTER PLLC, 7th Floor, 2000 M Street, N.W., Washington, DC, 20036-3307, US

(21) Appl. No.: 09/902,589

(22) Filed: Jul. 12, 2001

(51) Int. Cl. H05K 1/00; H05K 3/34

(52) U.S. Cl. 29/840; 174/250; 29/852

(57) ABSTRACT

A method for attaching an electronic component to a substrate having a patterned conductive layer underlying a dielectric layer includes: removing regions of the dielectric layer to form cavities having an exposed surface area of the conductive layer; filling the cavities with solder paste; heating the solder paste to form a convex surface which protrudes above the substrate surface, for receiving an electronic component for attachment; planarising the convex surface such that it and the surface of the substrate surface are substantially coplanar; placing contact pads of the electronic component adjacent the substrate such that the contact pads overlie given filled cavities; and reheating the solder so that it reflows and connects the electronic component to the substrate. The cavities preferably all have the same volume. If the ratio of exposed surface area to cavity volume is low, pillars form during reflow, spacing the component from the substrate.

### BACKGROUND OF THE INVENTION

The present invention relates to a method for attaching components to a substrate, such as a printed circuit board.

Connection of electronic components, including integrated circuits (IC's), to printed circuit boards (PCB's) has conventionally been done by dipping suitably prepared PCB's into a bath of molten solder. The molten solder coated areas onto which components were to be attached as well as regions there between which were intended to act as conductor tracks. Molten solder attached to, and was taken up by, areas of the PCB which were pre-coated with a desired solder pattern.

United States patent U.S. Pat. No. 5,172,853 discloses a technique of applying solder to printed circuit boards including the steps of applying solder paste onto the PCB through a mask or stencil, heating the solder so that it flows, and allowing the solder to cool, so as to form hump shaped solder bumps. These bumps are then pressed, so as to ensure the heights of all the bumps are the same. Careful dimensioning of the quantity of spider paste to be applied through the stencil is required, so that when flowed solder is pressed or rolled in order to planarise the cooled solder bumps, none of the solder protrudes beyond the surface of a stop mask layer integral with the substrate. Dimensioning the amounts of solder to be used, and configuring the shape of the solder is difficult. Deriving the specific mixture of solder so that it adopted the requisite characteristics is also difficult and time consuming. Also because different solders are used, each solder type having slightly different mixtures of metal alloy components and volatile fluxes, different thermal conductivities, specific heat capacities and surface tensions are present in the melted solder state. Recalibration of the amount and type of solder is therefore required for different type or mix of solders and/or each PCB application.

A disadvantage of applying solder paste through a stencil is that when the stencil is lifted away from the substrate. it sometimes removes small amounts of solder paste, thereby disturbing the intended layout of solder.

An object of the present invention is to provide an improved method for attaching components to a substrate.

### SUMMARY OF THE INVENTION

According to a first aspect of the present invention there is provided a method for attaching an electronic component to a substrate having a patterned electrically conductive layer underlying a dielectric layer, including the steps of: forming cavities in the dielectric layer, at least some cavities providing an exposed surface area of the electrically conductive layer, filling the cavities with solder paste, and heating the solder paste to a temperature below the eutectic point to form a convex surface which protrudes above the substrate surface, for receiving an electronic component for attachment.

The method preferably includes the further steps of: planarising the convex surface such that the convex surface of the solder and that of the substrate surface are substantially coplanar, placing an electronic component having contact pads adjacent said substrate such that the contact pads overlie given filled cavities, and reheating the solder so that it reflows and attaches the electronic component to the substrate, and forms an electrical contact between the contact pads and the patterned electrically conductive layer.

Advantageously, the ratio of the exposed surface area of the electrically conductive layer to the volume of a given cavity is sufficiently small that when the solder reflows it forms a pillar which has a height greater than the depth of the cavity, said pillar spacing the electronic component from the surface of the substrate. Preferably the shape of the exposed surface area is defined to provide concave and/or convex portions such that the pillars formed thereon have corresponding grooves and/or or ridges. The grooves and/or ridges preferably extend substantially normal to the surface of the substrate.

The cavities are conveniently arranged in an array and have substantially equal volumes, such that each cavity will be filled with a similar amount of solder, resulting in a desired shape of convex surface when heated.

According to a further aspect of the invention some cavities have defined therein primary and secondary cavities, which are dimensioned and arranged so that when the solder flows solder can pass from said primary to said secondary cavity, and vice versa, and provide electrical continuity between circuit networks resident in the construction of the substrate.

An advantage of the present invention over existing techniques is that solder will be present only where it is needed, because solder is applied directly into preformed cavities. There is no need to dip preformed PCB boards into molten solder baths. This reduces the need for monitoring and collection of solder fumes

Another advantage of the present invention is that packaging of components and ICs is no longer required. This is important because when heating of the assembled substrate and components occurs, in order to reflow the solder, a much less complex temperature profile is needed in the oven through which the assembled substrate passes. This simpler temperature profile is brought about by not having to control the thermal gradient in order not to thermally damage the myriad size and shape components or die packages all having different thermal conductivities and impedances. The fact that thermal control is easier reduces the capital cost of ovens as well as their operational and maintenance costs. Moreover it increases throughput as processing speeds are increased because overall dwell time in ovens is less, as a result of the more rapid heating cycles which can be applied to substrates.

Other advantageous aspects of the invention will become apparent during the detailed description below.

### BRIEF DESCRIPTION OF THE DRAWINGS

Embodiments of the invention will now be described, by way of example only, with reference to the accompanying schematic Figures, in which;

FIGS. 1a to 1f show sectional views through a substrate and illustrate key steps in a first method of fabrication,

FIGS. 2a to 2d show sectional views illustrating a second method of fabrication,

FIG. 3 shows plan views of alternative cavity shapes,

FIG. 4 shows a plan and cross section of a connection made between conductive layers in a substrate using the present invention, and

FIG. 5 shows plan views of contact pads and associated cavities.

### DETAILED DESCRIPTION OF THE INVENTION

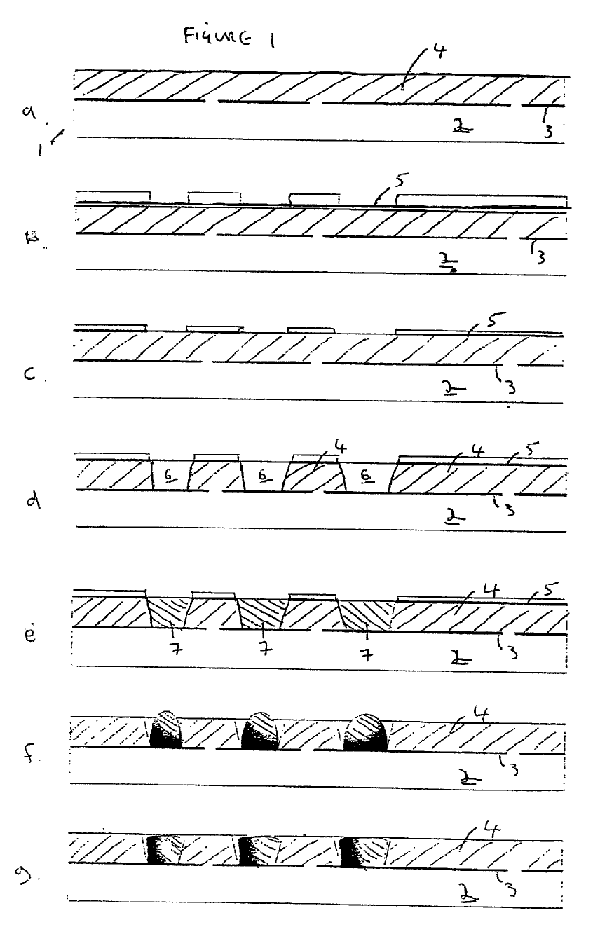

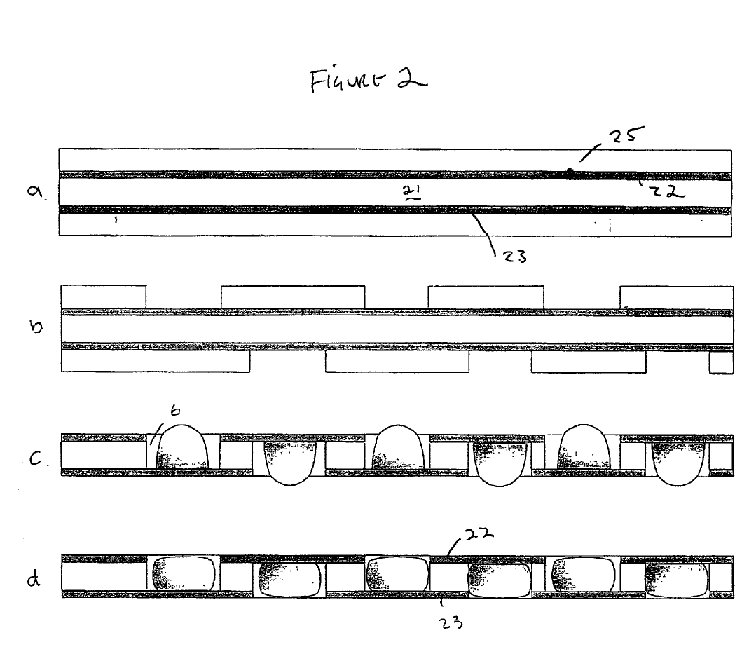

A first method according to the present invention is shown schematically in cross section in FIG. 1. The substrate (1) is a PCB comprising a dielectric layer (2) 80 microns thick, having a conventional patterned copper layer (3) on a major surface. The PCB can be a multilayer PCB, but only the top layer of copper is shown in the diagram. The surface of the substrate is coated with a 75 micron thick layer (4) of a photo-definable epoxy resin coating material, commercially available from a variety of circuit supply companies, and then a thin layer of copper (5) (typically 2 microns thick) is electrolessly deposited via a ionic transfer method, as shown in FIG. 1a. This copper layer is patterned and etched to form a stencil pattern using conventional photolithographic techniques, as shown in FIGS. 1b and 1c. After the resist is stripped, cavities (6) are formed in the epoxy resin layer using the patterned copper layer as a mask, as shown in FIG. 1d.

These cavities are preferably formed by laser ablation as described for example in our co-pending patent application number PCT/GB01/00823, which is incorporated herein by reference. Ablation may be achieved for example, with a CO₂, YAG or Excimer laser or an ion beam to dimensions of less than 20 microns on a side. The shape and volume of the cavity which receives the solder is important because this determines the amount of solder present. Cavity dimensions and cavity volume may be varied by using a different pulse sequence in a laser. Other techniques for forming cavities may be used as an alternative, for example ion beam or plasma etching, or wet etching, or milling. The cavity is cut sufficiently deep to expose parts of the patterned copper layer (3) on the original substrate surface. These exposed areas are sometimes called “land”. This land need not cover the whole of the bottom surface of the cavity, as explained later. Changing the ratio of land area to cavity volume changes the meniscus height of the solder deposit after reflow.

After the cavities (6) are formed, they are filled with solder paste, such as for example an alloy paste such as AgPb or SnPb, having particle sizes preferably less than 15 microns in diameter, very preferably less than 7 microns in diameter, thus forming plugs (7) as shown in FIG. 1e. In the present invention, the solder paste is preferably applied using a squeegee, which may be a resiliently deformable blade, for example a metal blade. The blade removes excess solder paste from the upper copper surfaces (8), whilst allowing the solder paste plugs to remain in the cavities. Other methods of selectively filling the cavities with solder paste may be used, such as for example coating the surface and passing it through rollers. An advantage with the present invention is that because the solder paste is applied directly to the surface of a PCB, there is no need to employ expensive solder paste stencils which may misregister the solder deposits and leave variable volumes of solder paste at the attachment sites.

The solder paste plugs are then heated to the solder eutectic temperature. This causes the solder to become molten, as the molten solder is allowed to cool surface tension forces cause the solder to ball up on any exposed copper land on the base of the cavity, as shown in FIG. 1f, forming a convex surface, meniscus or bump. In the present example, the solder eutectic temperature is 210° C. The substrates are removed from the oven and planarised, in the present example by urging the hot softened solder back into the cavities by applying pressure. Pressure can be applied using a platen type press, or pinch drive rollers. The resultant solder plug profile is shown in FIG. 1g. Essentially, in this embodiment of the method the cavities are made in a layer of dielectric carried by the original PCB.

U.S. Pat. No. 6,060,778 discloses a ball grid array package with high heat dissipation performance and low weight. When solder paste is applied to the surface of a PCB using a squeegee, for example in the fabrication of Ball Grid Arrays, there was a risk of occlusions occurring in recesses. Also upon cooling solder slump occurred. This was partly due to surface tension effects of melted solder and partly as a result of occlusions. These problems have been overcome in the present invention by heating solder to the eutectic point, at which point capillary action tends to draw the solder into the recess. Typically the ratio of metal alloy remaining after this heat treatment is approximately 49-52% of total original weight. This is because solder paste carrier is evaporated and solder material is drawn into cavities. At this stage a subsequent layer of solder paste may be applied so that cavities are part filled with the denser solder and less dense solder paste mix. Upon a second heat cycle all solder melts and homogenises so that cavities are properly filled. These stages may be automated.

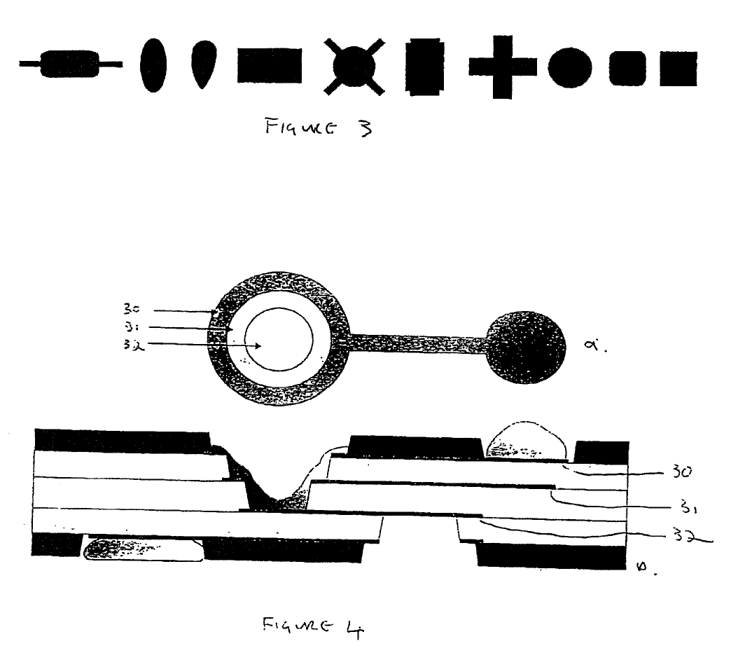

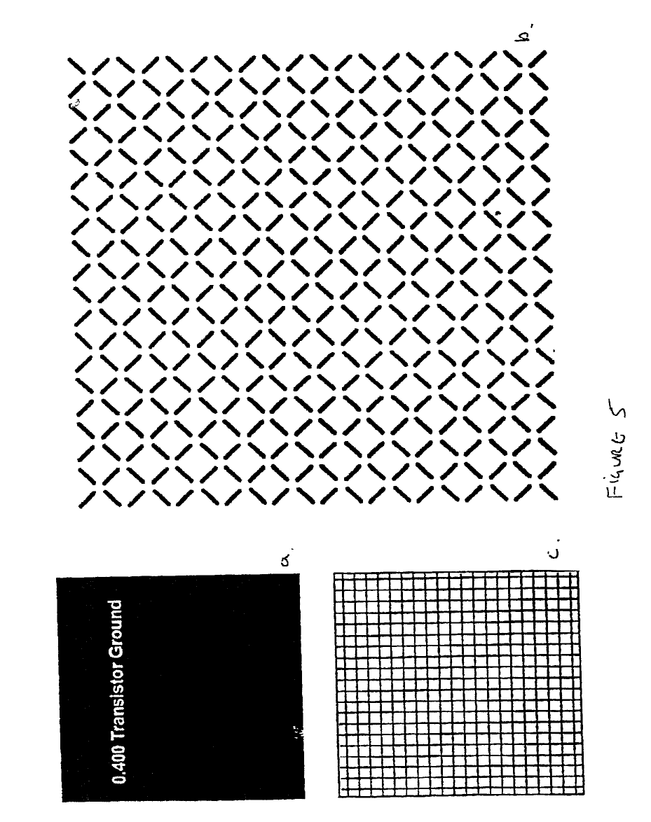

An alternative method of fabrication is shown schematically in cross section in FIG. 2. In this process, the starting point is an 80 micron thick dielectric sheet (21) having a 14 micron thick copper layer on both sides (22, 23) as shown in FIG. 2a. As a first step, the copper on both sides is patterned and etched photolithographically in the conventional manner, as shown in FIG. 2b. The resist 25 is then stripped. The cavities (6) are then formed in the original dielectric sheet 21 by laser ablation through the patterned copper layer 22 which acts as a mask, and the solder paste is selectively deposited into the cavities and heated to the eutectic temperature (as before) to give a structure as shown in FIG. 2c. The solder bumps are then planarised and the exposed copper 22 is stripped or pattern etched to give the structure as shown in FIG. 2d. One difference between the method of FIG. 1 and the method of FIG. 2 is that in the former cavities are formed in the photo imaged epoxy layer deposited on top of the PCB, whilst in the latter the cavities are formed in the original PCB.

After the fabrication steps shown in FIG. 1 or FIG. 2, a substantially flat substrate having defined surface areas comprising solder for electrical connection to underlying conductive tracks has been formed. Electronic components can then be placed on the substrate in the normal way by, for example, pick and place machinery. In one embodiment, the electronic components comprise IC's having solder bumps which are located to engage with the solder filled cavities in the substrate. In a further embodiment die which have contact pads but no solder bumps are attached directly, significantly simplifying and reducing the cost of the assembly process.

The assembly is then subjected to a solder reflow heating cycle. In the present example, where the solder has a eutectic temperature of 210° C., the temperature cycle used is as follows: temperature ramp up from room temperature to 195° C. taking 120 seconds, a temperature ramp up from 195° C. to 220° C. taking 30 seconds, followed by a temperature ramp down to 40° C. taking 90 seconds.

If both sides of a multi-layer PCB assembly are having components attached, this can be done at the same time using a single reflow step if desired, rather than two steps using different reflow temperatures. In this case, fixing means, typically an adhesive RMA flux, must be provided to keep the components in place on at least one side of the assembly whilst the solder reflow process is being performed.

There are many variables which have to be taken into consideration when developing a reflow temperature profile for affixing die to substrates. The alloy composition and the total mass and distribution of components on the substrate will have a major influence on the temperature curve for a specific assembly requirement. Normally the reflow temperature curve will be a uniform bell shaped profile of temperature versus time, lasting typically from 4 to 15 minutes in duration.

An important advantage of the present invention over existing techniques, and particularly that disclosed in U.S. Pat. No. 5,172,853, is that because cavity shapes and dimensions are predictable and uniform, solder geometry and behaviour is predictable. By judiciously varying one or more of the following factors it is possible to tailor the eventual height and profile of the solder surface. The key factors are:

a) the shape of the electrically conductive layer (which may be on a surface of the substrate or embedded therein) on which the solder is deposited. This can be defined prior to manufacture, or be changed by chemical etching and/or deposition following formation of the cavity. This conductive portion is often referred to as a ‘land’.

b) the area of the conductive land is important because it helps to determine the rate of heat transfer (i.e. cooling of the solder) and is important in determining the shape of the reflowed solder bump.

c) the amount and type of solder present in the cavity, which depends on the flux or carrier component of the solder paste, determines the final volume of solder. From this and knowledge of the types of volatile components which are present in the flux, an indication can be obtained about the composition of the solder, including what amount of metal alloy remains after reflow. Solder paste can be manufactured with varying alloy loadings—for example from 48% to 60% by volume, corresponding to 88-95% by weight.

d) the ratio of exposed area and shape of the land to volume of solder—this determines the height the solder bump will rise to.

e) the surface tension of the molten metal alloy present in the solder which affects how the reflowed solder will behave. Different alloys will in general have different surface tensions, and the surface tension may vary with temperature.

Because solder geometry is more predictable using the present invention, several advantages follow. Firstly, amounts of solder (which can sometimes be very expensive as solder may contain precious metals such as silver or gold) can be predicted with greater accuracy. Costing, therefore, becomes simpler and more reliable. Also, the present method is superior to existing techniques in that there is much less material waste as solder paste stencils are eliminated. Spurious solder balls are also eliminated and it follows from this that as less spurious surface material is present, the risk of solder shorts is reduced greatly. More importantly because solder “lift off” does not occur (as no stencil is used), there is no risk of removed solder material falling onto a PCB and causing a short circuit.

The apertures defining slots or cavities may take many different forms. For example, apertures may be circular, ovaloid, lozenge or in the form of long narrow' slots. The shape of the aperture (and the conductive land within it) is one of the key features which affects the characteristics of the solder as previously mentioned. The depth of the aperture can also be varied by controlling the ablation means. It is possible to achieve cavities whose ratio of depth to diameter is from less than 1:1 up to more than 10:1 if focussed beams are used.

In a particularly preferred embodiment, cross-sectional exposed copper areas may be star shaped, fluted, fan-shaped, trefoil, diamond or in the form of a ring. Examples of such shapes are shown in FIG. 3 in plan view. Advantages of such non-circular apertures are that the resulting solder deposits are more structurally dynamic and may be formed to produce specific mechanical characteristics. This aspect of the invention provides an improved method of attaching semiconductors to the circuit substrate, when the ratio of the exposed surface area of the electrically conductive layer to the volume of a given cavity is sufficiently small, the solder reflows to form a pillar which has a height greater than the depth of the cavity. The shape of the exposed surface area or land defines the shape of the pillar—solder regrowth tends to follow the surface defined by the perimeter of the land—concave and/or convex portions will result in the pillars formed thereon having corresponding grooves and/or or ridges. Typically, the grooves and/or ridges extend substantially normal to the surface of the substrate. These pillars can support components away from the surface of the substrate, and define a gap between the component and the substrate. This creates a natural channel between the component and PCB after die attach, thereby enhancing cooling and removing the need for expensive component packaging.

An important advantage of using a laser to remove regions, so as to define cavities, is that very small volumes of material can be removed quickly and the ablation process is repeatable. Similarly narrow interconnect tracks can be defined by removing non-conductive substrate. Typically a characteristic dimension of an interconnect feature is less than 10 microns. This facilitates multi-layer board configurations. Multilayer arrays of boards may be fabricated by overlaying one pre-formed PCB on another, thereby creating double-sided surface mount assemblies. An advantage of using the method for forming double sided surface mount assemblies, is that only a single reflow step in the fabrication method is required, as surface tension holds solder in the cavities.

Another aspect to the present invention is that the use of conventional vias for connecting copper layers in a multilevel PCB can be avoided, if desired. This is shown schematically in FIG. 4. Once planarised, solder sites may be plugged and interconnected one layer to another. Interconnection of layers is preferably achieved by using routing patterns unique to a specific design. By arranging the routing path inside a conventional ‘footprint’ pattern, the need to use conventional vias is removed. FIG. 4a shows a plan view of the metal layers 30, 31 and 32, whilst FIG. 4b shows the same layers in cross-section, with concentric ablated vias connected together by a single flowed solder plug, applied using the method of the present invention.

Using the present invention, large solder areas corresponding to die contact pads are preferably replaced by many smaller solder paste filled cavities on the PCB assembly, such that many smaller cavities cover the same area. This increases the process reliability because of redundancy and uniformity. This is shown schematically in FIG. 5. FIG. 5a shows a typical contact pad, 5b shows an array of cavities which can be used on top of such a pad in the underlying substrate, or underneath such a pad on an electronic component being attached to the substrate. FIG. 5c shows a criss-cross pattern which can be used in the underlying substrate instead of the large single contact pad of FIG. 5a. If one or two cavities fail to produce a good contact to the die this does not matter, as there are many more cavities which on average will provide good contact. Large numbers of slots or holes may be formed in arrays. Redundancy can be incorporated into an array pattern or layout. Slots can be arranged parallel one to another and arranged in rows. In turn rows may be arranged so that they are configured in a herringbone pattern. Redundancy of slots means that only specific slots need to be used for connection of components, thus simplifying the production of circuit boards, as designs can be reduced to substantially the same base pattern. A key advantage of inherent redundancy is that the cost and speed of board production are not affected, because lasers are used to ablate cavities in order to form slots. This reduces the cost of tailoring boards as well as simplifying their processing. Typically rates of slot production are on the order of 4 to 40 slots per second depending on the size of the slot and the type of laser employed for the ablation of the material.

A subtle advantage of having large numbers of small slots, and only using the number and location of sufficient slots for each connector of a die or component, is that is that thermal conditions for reflow are relatively straightforward to predict and control because the thermal characteristics of the actual number of slots used is easy to calculate.

Unlike with conventional PCB fabrication, the solder filled cavities in the present invention are not necessarily confined to uniform patterns in areas corresponding to component contact pads. Cavities can be formed anywhere along conductive tracks.

According to another aspect of the invention there is provided a method for connecting a component to a substrate, comprising the steps of; preparing a cavity on the substrate, the cavity being of a predetermined volume for receiving solder so that the solder is in contact with a conductive layer, depositing solder in said cavity, the cavity having a pre defined meniscus location which is dimensioned and arranged so that the surface tension forces of the solder as it cools from liquidus to solid are sufficient to provide a lateral component force which provides a centering effect for accurately locating the electrical contacts of the component.

This aspect of the invention ensures that components are correctly oriented and located on solder surfaces.

An important advantage of the present invention is that if the conductive land does not cover the entire base of a cavity, when the solder is reflowed columns of solder can emerge from the cavities or slots, and in certain preferred geometries, engage with the component or Integrated Circuit (die) pins, thus locating the die or component, and when the solder cools and solidifies, holding the die or component in a predetermined orientation spaced a predetermined distance away from the surface of the PCB/substrate.

Although in the above embodiments AgPb or SnPb solder paste was used, other materials such as Tin Silver Copper alloys or other lead free solder pastes may be employed.

1. A method for attaching an electronic component to a substrate having a patterned electrically conductive layer underlying a dielectric layer, including the steps of:
a. forming cavities in the dielectric layer, at least some cavities providing an exposed surface area of the electrically conductive layer,
b. filling the cavities with solder paste, and
c. heating the solder paste to the eutectic point of the alloy to form a convex surface which protrudes above the substrate surface, for receiving an electronic component for attachment.

2. A method as claimed in claim 1 including the steps of:
d. planarising the convex surface such that the convex surface of the solder and that of the substrate surface are substantially coplanar,
e. placing an electronic component having contact pads adjacent said substrate such that the contact pads overlie given filled cavities, and
f. reheating the solder so that it reflows and attaches the electronic component to the substrate, and forms an electrical contact between the contact pads and the patterned electrically conductive layer.

3. A method as claimed in claim 2 in which the ratio of the exposed surface area of the electrically conductive layer to the volume of a given cavity is sufficiently small that when the solder reflows it forms a pillar which has a height greater than the depth of the cavity, said pillar spacing the electronic component from the surface of the substrate.

4. A method as claimed in claim 3 in which the shape of the exposed surface area is defined to provide concave and/or convex portions such that the pillars formed thereon have corresponding grooves and/or or ridges.

5. A method as claimed in claim 4 in which the grooves and/or ridges extend substantially normal to the surface of the substrate.

6. A method as claimed in claim 1 in which the cavities are arranged in an array and have substantially equal volumes, such that each cavity will be fitted with a uniform amount of solder, resulting in a desired shape of convex surface when heated.

7. A method as claimed in claim 2 in which some cavities have defined therein primary and secondary cavities, which are dimensioned and arranged so that when the solder flows solder can pass from said primary to said secondary cavity, and vice versa, whereby the capillary action in the molten solder is sufficient to provide a electrically conductive path between two layers.

8. A substrate having an electronic component attached to it using a method as claimed in any preceding claim.
